(19) United States
(12) Patent Application Publication
(10) Pub. No.: US 2024/0234838 A1
(43) Pub. Date: Jul. 11, 2024

(54) RECHARGEABLE BATTERY PACK

(71) Applicant: SAMSUNG SDI CO., LTD., Yongin-si (KR)

(72) Inventor: Jaepil AHN, Yongin-si (KR)

(21) Appl. No.: 18/370,538

(22) Filed: Sep. 20, 2023

(30) Foreign Application Priority Data
Jan. 9, 2023 (KR) 10-2023-0002905

(51) Int. Cl. H01M 10/42; H01M 50/202; H01M 50/30; H01M 50/519

(52) U.S. Cl. CPC H01M 10/425; H01M 50/202; H01M 50/30; H01M 50/519

(57) ABSTRACT

A rechargeable battery pack includes a cell assembly including at least one battery cell; a frame accommodating the cell assembly; a cell monitor circuit board on an upper portion of the cell assembly; and a flexible printed circuit board electrically connected to the cell assembly, the flexible printed circuit board being configured to sense the battery cell and being electrically connected to the cell monitor circuit board, wherein the cell monitor circuit board and the flexible printed circuit board are electrically connected to each other through an electrically conductive adhesive.

### CROSS-REFERENCE TO RELATED APPLICATION

This application claims priority to and the benefit of Korean Patent Application No. 10-2023-0002905 filed in the Korean Intellectual Property Office on Jan. 9, 2023, the entire contents of which are incorporated herein by reference.

### BACKGROUND

### 1. Field

Embodiments relate to a rechargeable battery pack.

### 2. Description of the Related Art

A rechargeable battery is a battery that is charged and discharged repeatedly, unlike a primary battery. Low-capacity rechargeable batteries may be used in small, portable electronic devices such as cell phones, laptop computers, and camcorders. High-capacity and high-density rechargeable batteries may be used to be power sources to drive motors in hybrid and electric vehicles, or for energy storage.

The rechargeable battery may include an electrode assembly that charges and discharges current, a case that accommodates the electrode assembly and an electrolyte, and electrode terminals that are connected to the electrode assembly and extend to the outside of the case. The electrode assembly may be formed of the jellyroll type, which is formed by winding the electrodes and separator.

### SUMMARY

The embodiments may be realized by providing a rechargeable battery pack including a cell assembly including at least one battery cell; a frame accommodating the cell assembly; a cell monitor circuit board on an upper portion of the cell assembly; and a flexible printed circuit board electrically connected to the cell assembly, the flexible printed circuit board being configured to sense the battery cell and being electrically connected to the cell monitor circuit board, wherein the cell monitor circuit board and the flexible printed circuit board are electrically connected to each other through an electrically conductive adhesive.

The electrically conductive adhesive may include a solder or a conductive glue.

The cell monitor circuit board may include plurality of circuit lines, and a conductive pad portion at an end of each circuit line of the plurality of circuit lines, the conductive pad portion being electrically connected to the flexible printed circuit board.

The conductive pad portion may protrude from the circuit line, has a width greater than a width of the circuit line, and is electrically connected to the cell monitor circuit board through the electrically conductive adhesive.

The conductive pad portion may include a first expansion pad protruding from a first side of the circuit line in a width direction of the circuit line; and a second expansion pad protruding from a second side of the circuit line in the width direction of the circuit line.

The conductive pad portion may include a rounded groove between the first expansion pad and the second expansion pad.

The electrically conductive adhesive may be a cream solder in the rounded groove, adhered thereto by laser heat, and electrically connected to the cell monitor circuit board.

The electrically conductive adhesive may be a wire solder in the rounded groove, adhered thereto by laser heat, and electrically connected to the cell monitor circuit board.

The plurality of circuit lines may further include a first sub-pad portion at a position spaced apart from the conductive pad portion and into which the electrically conductive adhesive is inserted and electrically connected to the cell monitor circuit board.

The first sub-pad portion may include a through-hole therein into which the electrically conductive adhesive is inserted, and may protrude from both sides of the circuit line in a width direction of the circuit line.

The cell monitor circuit board may include a second sub-pad portion thereon at a position spaced apart from the first sub-pad portion and filled with the electrically conductive adhesive connected to the flexible printed circuit board.

The second sub-pad portion may include a ring pad penetrating the cell monitor circuit board at a position spaced apart from the first sub-pad portion with no contact with said circuit lines, and the ring pad may include a long hole therein.

The cell monitor circuit board may include a gas vent portion at a position spaced apart from the conductive pad portion.

The gas vent portion may include a reinforcing pad electrically connected to the plurality of circuit lines at a position spaced apart from the conductive pad portion and including at least one gas vent hole therein.

The reinforcing pad may be at a position spaced apart from the conductive pad portion, has a width greater than the width of the plurality of circuit lines, and has an oblong shape along the circuit lines.

The at least one gas vent hole may include a plurality of gas vent holes along a lengthwise direction of the reinforcing pad.

The plurality of gas vent holes may penetrate the reinforcing pad and the cell monitor circuit board together.

A surface of the electrically conductive adhesive may be coated with a conformal coating.

The conformal coating may be applied around an edge of the cell monitor circuit board to which the conductive pad portion is attached, and may be applied to a portion of the edge of the cell monitor circuit board together with a portion of the flexible printed circuit board.

### BRIEF DESCRIPTION OF THE DRAWINGS

Features will be apparent to those of skill in the art by describing in detail exemplary embodiments with reference to the attached drawings in which:

FIG. 1 is a perspective view schematically illustrating a rechargeable battery pack according to a first embodiment of the present disclosure.

FIG. 2 is a view of main components schematically illustrating a state in which a conductive pad portion and a first sub-pad portion are formed at a connection position between a cell monitor circuit board and a flexible printed circuit board in FIG. 1.

FIG. 3 is a view of main components schematically illustrating a state in which the flexible printed circuit board and the cell monitor circuit board in FIG. 2 are electrically connected to each other by an electrically conductive adhesive (solder).

FIG. 4 is a view of main components illustrating a state in which the conductive adhesive (solder) in FIG. 3 has been applied.

FIG. 5 is a view of main components schematically illustrating a state in which the conductive adhesive in FIG. 4 has been removed.

FIG. 6 is a view of main components schematically illustrating a state in which a conductive pad portion and a second sub-pad portion are formed at a connection position between a cell monitor circuit board and a flexible printed circuit board according to a second embodiment of the present disclosure.

FIG. 7 is a view of main components schematically illustrating a state in which a conductive pad portion and a gas vent portion are formed at a connection position between a cell monitor circuit board and a flexible printed circuit board according to a third embodiment of the present disclosure.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present. Like reference numerals refer to like elements throughout.

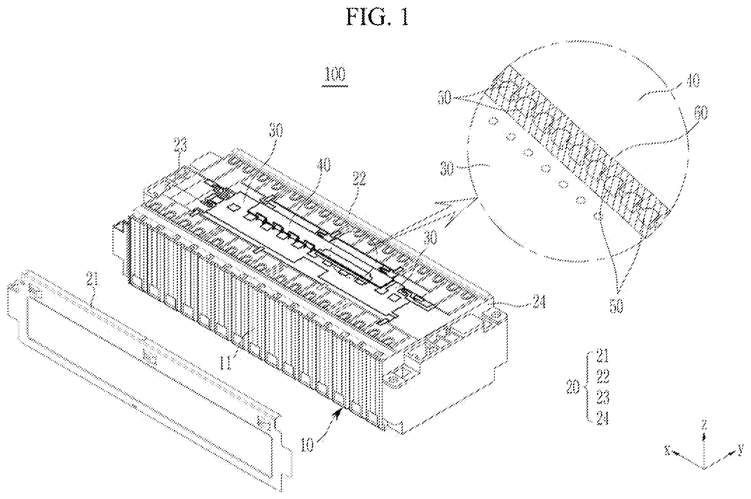

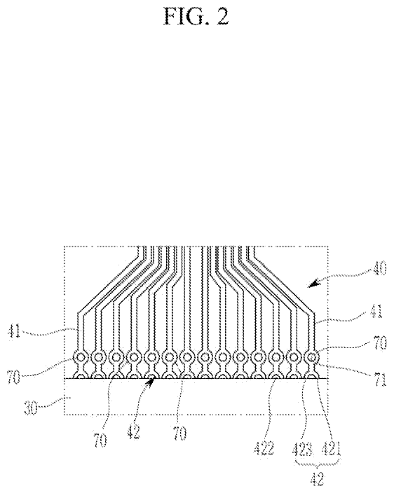

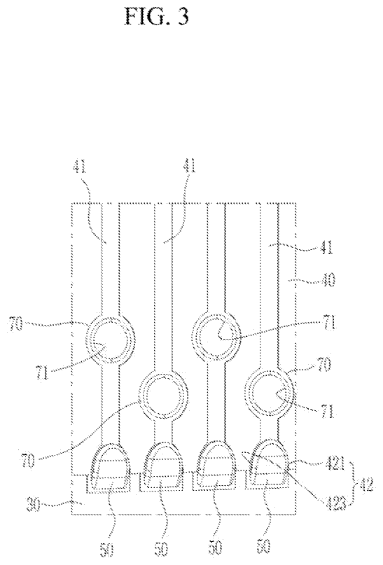

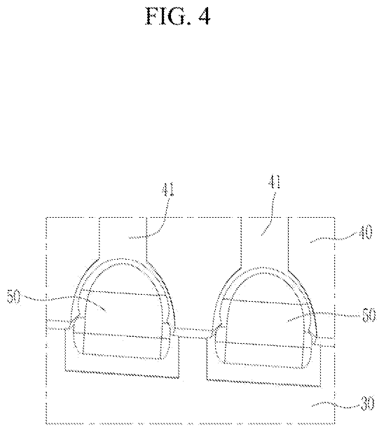

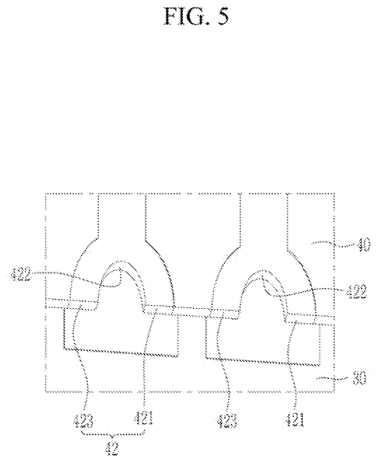

FIG. 1 is a perspective view schematically illustrating a rechargeable battery pack according to a first embodiment of the present disclosure, FIG. 2 is a view of main components schematically illustrating a state in which a conductive pad portion and a first sub-pad portion are formed at a connection position between a cell monitor circuit board and a flexible printed circuit board in FIG. 1, FIG. 3 is a view of main components schematically illustrating a state in which the flexible printed circuit board and the cell monitor circuit board in FIG. 2 are electrically connected to each other by an electrically conductive adhesive (solder), FIG. 4 is a view of main components illustrating a state in which the conductive adhesive (solder) in FIG. 3 has been applied, and FIG. 5 is a view of main components schematically illustrating a state in which the conductive adhesive in FIG. 4 has been removed.

With reference to FIGS. 1 to 5, a rechargeable battery pack 100 according to a first embodiment of the present disclosure may include a cell assembly 10 including at least one battery cell 11, a frame 20 accommodating the cell assembly 10, a cell monitor circuit board 40 on an upper portion of the cell assembly 10, and a flexible printed circuit board (FPC) 30 electrically connected to the cell assembly 10 to sense (e.g., a state of charge, health, or other properties of) a battery cell 11 and being electrically connected to the cell monitor circuit board 40. In an implementation, the flexible printed circuit board 30 and the cell monitor circuit board 40 may be electrically connected to each other by or through an electrically conductive adhesive 50.

A plurality of the battery cells 11 may be configured as a rechargeable battery that is repeatedly charged and discharged.

The frame 20 may include a first side frame 21 configured to support one side surface of the plurality of battery cells 11, a second side frame 22 configured to support the other side surface of the plurality of battery cells 11, a first end frame 23 connected at respective ends of the first side frame 21 and the second side frame 22, and a second end frame 24 connected at respective other ends of the first side frame 21 and the second side frame 22.

The first side frame 21 may support one side of the plurality of battery cells 11.

The second side frame 22 may support the other side of the plurality of battery cells 11.

The first end frame 23 may connect the respective one ends of the first side frame 21 and the second side frame 22 to connect the first side frame 21 and the second side frame 22. In an implementation, one end of the first end frame 23 may be connected to one end of the first side frame 21 by a fastener, and the other end of the first end frame 23 may be connected to one end of the second side frame 22 by a fastener.

The second end frame 24 may connect the respective the other ends of the first side frame 21 and the second side frame 22 to connect the first side frame 21 and the second side frame 22. In an implementation, one end of the second end frame 24 may be connected to the other end of the first side frame 21 by a fastener, and the other end of the second end frame 24 may be connected to the other end of the second side frame 22 by a fastener.

The flexible printed circuit board 30 may be on an upper portion of the frame 20, which is electrically connected to the cell assembly 10 and configured to sense the battery cells 11.

The cell monitor circuit board 40 may be on the upper portion of the cell assembly 10.

The cell monitor circuit board 40 may be a cell supervision circuit (CSC) or a cell monitor circuit (CMC).

The cell monitor circuit board 40 may receive sensing signals of the battery cell 11 through the flexible printed circuit board 30 and may be capable of identifying an abnormal operating state of the battery cell 11.

The cell monitor circuit board 40 may be on an upper side of the cell assembly 10, and may be at an approximately central position in a lengthwise direction of the cell assembly 10.

In an implementation, the cell monitor circuit board 40 may be at the approximately central position of the upper portion of the cell assembly 10 to allow for a reliable electrical connection while preventing interference occurring in the process of connecting the flexible printed circuit board 30 to the cell monitor circuit board 40.

The flexible printed circuit board 30 may be electrically connected at one side thereof to the cell assembly to sense the battery cells 11 and may be electrically connected at the other side thereof to the cell monitor circuit board 40.

The flexible printed circuit board 30 may be electrically connected to the cell monitor circuit board 40 at the approximately central position of the upper portion of the cell assembly 10.

In an implementation, the electrically conductive adhesive 50 may be applied as a solder to electrically connect the flexible printed circuit board 30 and the cell monitor circuit board 40. In an implementation, the electrically conductive adhesive 50 may be applied as a conductive glue. Hereinafter, the application of the electrically conductive adhesive 50 as a solder will be described in more detail. In the following, the electrically conductive adhesive and solder use the same reference numeral.

The cell monitor circuit board 40 may have a conductive pad portion 42 for solder 50 to adhere thereto.

The conductive pad portion 42 is a portion connected to the cell monitor circuit board 40 to which the solder 50 may be adhered, and may be electrically connected to a circuit line 41 of the cell monitor circuit board 40.

The conductive pad portion 42 may protrude from the circuit line 41 at a size greater than a width of the circuit line 41 (e.g., the conductive pad portion 42 may have a width greater than a width of the circuit line 41) and may be electrically connected to the flexible printed circuit board 30 through the solder 50.

With reference again to FIGS. 3 and 4, the conductive pad portion 42 may include a first expansion pad 421 protruding from a first side of the circuit line 41 in a width direction, and a second expansion pad 423 protruding from a second side of the circuit line 41 in a width direction. Here, the first and second sides are in opposite directions.

The first expansion pad 421 may be connected to the circuit line 41 in a state that protrudes from the circuit line 41 in a direction of the first side with respect to a center of an end of the circuit line 41.

The first expansion pad 421 may be connected to the circuit line 41 (e.g., may continuously extend from and include the same material as the circuit line 41), may protrude in the direction of the first side, and may protrude from the circuit line 41 in a rounded shape.

The second expansion pad 423 may have the same or similar shape as the first expansion pad 421 and may protrude from the circuit line 41 in a direction of the second side opposite to the direction of the first side (e.g., may be a mirror image of the first expansion pad 421).

The second expansion pad 423 may be connected to the circuit line 41 (e.g., may continuously extend from and include the same material as the circuit line 41), may protrude in the direction of the second side, and may protrude from the circuit line 41 in a rounded shape.

In an implementation, the first expansion pad 421 and the second expansion pad 423 may each protrude in a rounded shape in a direction opposite to each other. A rounded groove 422 may be between the first expansion pad 421 and the second expansion pad 423, and the first expansion pad 421 and the second expansion pad 423 may protrude while being electrically connected to the end of the circuit line 41.

In an implementation, the rounded groove 422 may be between the first expansion pad 421 and the second expansion pad 423 to provide sufficient space for the solder 50 to be filled while increasing a surface area of the portion to which the solder 50 is applied, thereby facilitating a more robust electrical connection.

In an implementation, the first expansion pad 421 and the second expansion pad 423 may be at the end of the circuit line 41, and the application area of the solder 50 may be maximized, compared to a state in which the first expansion pad 421 and the second expansion pad 423 are not formed.

A surface of the solder 50 connecting the flexible printed circuit board 30 to the cell monitor circuit board 40 may be treated with a conformal coating 60 (see FIG. 1).

The conformal coating 60 may be applied to cover an entire outer surface of the solder 50 and may be cured to connect the flexible printed circuit board 30 and the cell monitor circuit board 40.

In an implementation, a first sub-pad portion 70 may be on the plurality of circuit lines 41. The first sub-pad portion 70 may be at a position spaced apart from the conductive pad portion 42 and may be electrically connected to the cell monitor circuit board 40, e.g., by inserting the electrically conductive adhesive 50.

The first sub-pad portion 70 may protrude from or be on the circuit line 41 at a position spaced apart from the conductive pad portion 42 by a predetermined distance, and may include a through-hole 71 therein.

The first sub-pad portion 70 may protrude from the circuit line 41, e.g., may have a rounded shape at a position spaced apart from the conductive pad portion 42, and may be electrically connected to the circuit line 41.

In an implementation, as illustrated in the drawings, the first sub-pad portion 70 may have a rounded shape, or may be modified to a variety of shapes, including polygonal.

In an implementation, the solder 50 may be inserted into an interior of the through-hole 71 of the first sub-pad portion 70 to electrically connect the flexible printed circuit board 30 and the cell monitor circuit board 40 to each other, thereby securing a more robust electrical connection stiffness.

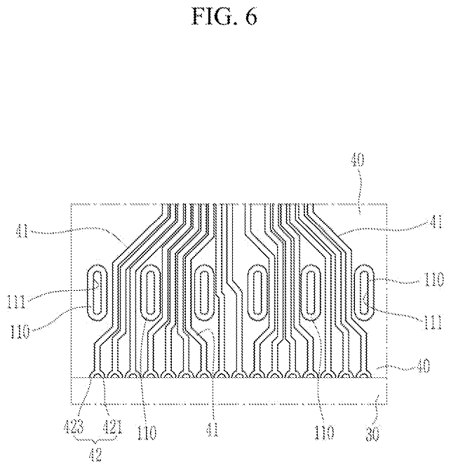

FIG. 6 is a view of main components schematically illustrating a state in which a conductive pad portion and a second sub-pad portion are formed at a connection position between a cell monitor circuit board and a flexible printed circuit board according to a second embodiment of the present disclosure. Reference numerals that are the same as those in FIGS. 1 to 4 refer to the same or similar features, the same or similar members, and the specific description thereof may be omitted hereinafter.

As illustrated in FIG. 6, the cell monitor circuit board 40 of a rechargeable battery pack according to a second embodiment of the present disclosure may have a second sub-pad portion 110 at a position spaced apart from the conductive pad portion 42.

This second sub-pad portion 110 may be filled with the electrically conductive adhesive 50 and may be connected to the flexible printed circuit board 30.

In an implementation, the second sub-pad portion 110 may be a ring pad that penetrates the cell monitor circuit board 40 at a position spaced apart from the first sub-pad portion 70 or the circuit line 41 with no contact with the circuit line 41. Hereafter, the second sub-pad portion and the ring pad use the same reference numeral.

The ring pad 110 may be on the cell monitor circuit board 40 at a position spaced apart from a position of the first sub-pad portion 70, and may penetrate the cell monitor circuit board 40 without being in contact with the circuit line 41.

In an implementation, the cell monitor circuit board 40 may include plurality of ring pads 110 spaced apart from each other.

The ring pad 110 may be elongate in a lengthwise direction along which the circuit line 41 extends, and may be in an interior of the cell monitor circuit board 40, such that a long hole 111 may have a long hole shape (e.g., oblong) in the lengthwise direction.

The long hole 111 of the ring pad 110 may be filled with the electrically conductive adhesive 50, such that the cell monitor circuit board 40 and the flexible printed circuit board 30 may be more firmly fixed to each other by an adhesive force of the electrically conductive adhesive 50.

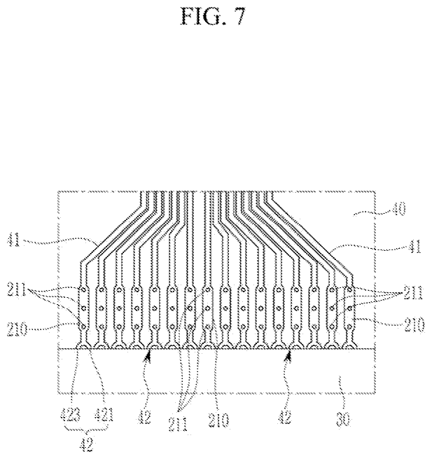

FIG. 7 is a view of main components schematically illustrating a state in which a conductive pad portion and a gas vent portion are formed at a connection position between a cell monitor circuit board and a flexible printed circuit board according to a third embodiment of the present disclosure. Reference numerals that are the same as those in FIGS. 1 to 5 refer to the same or similar features, the same or similar members, and the specific description thereof may be omitted hereinafter.

As illustrated in FIG. 7, the cell monitor circuit board 40 of a rechargeable battery pack according to a third embodiment of the present disclosure may have a gas vent portion 210 at a position spaced apart from the conductive pad portion 42.

The gas vent portion 210 may be electrically connected to the plurality of circuit lines at a position spaced apart from the conductive pad portion 42 and may be a reinforcing pad with a gas vent hole 211 therein. Hereafter, the gas vent portion and reinforcing pad use the same reference numeral.

The reinforcing pad 210 may be on the cell monitor circuit board 40 at a position (e.g., inwardly) spaced apart from a position of the conductive pad portion 42, and may have an oblong shape along the circuit line 41 on the cell monitor circuit board 40.

The reinforcing pad 210 may be elongate along the lengthwise direction of the circuit line 41, may have a width greater than the width of the circuit line 41, and may be in the interior of the cell monitor circuit board 40.

A plurality of gas vent holes 211 may be in the reinforcing pad 210.

In an implementation, the gas generated in the process in which the electrically conductive adhesive is fixed may be easily discharged to the outside through the gas vent hole 211, and accordingly, the fixation force by the electrically conductive adhesive 50 may be further improved, thereby improving the durability of the electrically connected cell monitor circuit board 40 and the flexible printed circuit board 30.

By way of summation and review, a flexible printed circuit (FPC) board may be electrically connected to a cell monitor circuit board (e.g., cell supervision circuit, CSC or cell monitor circuit. CMC) using a connector.

The circuitry connected to the connector could be damaged in the process of attaching and detaching the connector, which could reduce the durability.

When the cell monitor circuit board is installed on an upper portion of a cell module, damage, e.g., tearing of the flexible printed circuit board, could occur in the process of attaching and detaching the connector.

One or more embodiments may provide a rechargeable battery pack having an enhanced electrical connection stiffness of a flexible printed circuit board and a cell monitor circuit board.

One or more embodiments may provide a rechargeable battery pack capable of electrically connecting a flexible printed circuit board and a cell monitor circuit board with an electrically conductive adhesive without the use of a connector.

According to an embodiment, it is possible to electrically connect the flexible printed circuit board and the cell monitor circuit board using the electrically conductive adhesive such as a solder without using separate terminals, thereby enabling a stable connection while preventing open circuits caused by compression damage at the circuit connection points.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A rechargeable battery pack, comprising:
a cell assembly including at least one battery cell;
a frame accommodating the cell assembly;
a cell monitor circuit board on an upper portion of the cell assembly; and
a flexible printed circuit board electrically connected to the cell assembly, the flexible printed circuit board being configured to sense the battery cell and being electrically connected to the cell monitor circuit board,
wherein the cell monitor circuit board and the flexible printed circuit board are electrically connected to each other through an electrically conductive adhesive.

2. The rechargeable battery pack as claimed in claim 1, wherein the electrically conductive adhesive includes a solder or a conductive glue.

3. The rechargeable battery pack as claimed in claim 2, wherein the cell monitor circuit board includes:
plurality of circuit lines, and
a conductive pad portion at an end of each circuit line of the plurality of circuit lines, the conductive pad portion being electrically connected to the flexible printed circuit board.

4. The rechargeable battery pack as claimed in claim 3, wherein the conductive pad portion protrudes from the circuit line, has a width greater than a width of the circuit line, and is electrically connected to the cell monitor circuit board through the electrically conductive adhesive.

5. The rechargeable battery pack as claimed in claim 4, wherein the conductive pad portion includes:
a first expansion pad protruding from a first side of the circuit line in a width direction of the circuit line; and
a second expansion pad protruding from a second side of the circuit line in the width direction of the circuit line.

6. The rechargeable battery pack as claimed in claim 5, wherein the conductive pad portion includes a rounded groove between the first expansion pad and the second expansion pad.

7. The rechargeable battery pack as claimed in claim 6, wherein the electrically conductive adhesive is a cream solder in the rounded groove, adhered thereto by laser heat, and electrically connected to the cell monitor circuit board.

8. The rechargeable battery pack as claimed in claim 7, wherein the electrically conductive adhesive is a wire solder in the rounded groove, adhered thereto by laser heat, and electrically connected to the cell monitor circuit board.

9. The rechargeable battery pack as claimed in claim 3, wherein the plurality of circuit lines further includes a first sub-pad portion at a position spaced apart from the conductive pad portion and into which the electrically conductive adhesive is inserted and electrically connected to the cell monitor circuit board.

10. The rechargeable battery pack as claimed in claim 9, wherein the first sub-pad portion:
includes a through-hole therein into which the electrically conductive adhesive is inserted, and
protrudes from both sides of the circuit line in a width direction of the circuit line.

11. The rechargeable battery pack as claimed in claim 10, wherein the cell monitor circuit board includes a second sub-pad portion thereon at a position spaced apart from the first sub-pad portion and filled with the electrically conductive adhesive connected to the flexible printed circuit board.

12. The rechargeable battery pack as claimed in claim 11, wherein:
the second sub-pad portion includes a ring pad penetrating the cell monitor circuit board at a position spaced apart from the first sub-pad portion with no contact with said circuit lines, and
the ring pad includes a long hole therein.

13. The rechargeable battery pack as claimed in claim 3, wherein the cell monitor circuit board includes a gas vent portion at a position spaced apart from the conductive pad portion.

14. The rechargeable battery pack as claimed in claim 13, wherein the gas vent portion includes a reinforcing pad electrically connected to the plurality of circuit lines at a position spaced apart from the conductive pad portion and including at least one gas vent hole therein.

15. The rechargeable battery pack as claimed in claim 14, wherein the reinforcing pad is at a position spaced apart from the conductive pad portion, has a width greater than the width of the plurality of circuit lines, and has an oblong shape along the circuit lines.

16. The rechargeable battery pack as claimed in claim 15, wherein the at least one gas vent hole includes a plurality of gas vent holes along a lengthwise direction of the reinforcing pad.

17. The rechargeable battery pack as claimed in claim 16, wherein the plurality of gas vent holes penetrates the reinforcing pad and the cell monitor circuit board together.

18. The rechargeable battery pack as claimed in claim 3, wherein a surface of the electrically conductive adhesive is coated with a conformal coating.

19. The rechargeable battery pack as claimed in claim 18, wherein the conformal coating is applied around an edge of the cell monitor circuit board to which the conductive pad portion is attached, and is applied to a portion of the edge of the cell monitor circuit board together with a portion of the flexible printed circuit board.
